(19) United States
(12) Patent Application Publication
(10) Pub. No.: US 2002/0170677 A1
(43) Pub. Date: Nov. 21, 2002

(54) RF power process apparatus and methods

(76) Inventors: Steven D. Tucker, Matthews, NC (US); Jason F. Elston, Matthews, NC (US); Russell F. Jewett, Charlotte, NC (US)

Correspondence Address: LARRY WILLIAMS, 122 CALISTOGA ROAD, PMB-301, SANTA ROSA, CA, 95409-3702, US

(21) Appl. No.: 10/104,468

(22) Filed: Mar. 22, 2002

Related U.S. Application Data
(60) Provisional application No. 60/282,081, filed on Apr. 7, 2001.

(51) Int. Cl. C23F 1/00; C23C 16/00

(52) U.S. Cl. 156/345.48; 118/723 I

(57) ABSTRACT

Described are methods and apparatus for coupling RF power. In one embodiment, the method includes the step of flowing an RF current through an RF induction coil having a sufficiently large surface area and a low profile that results in effective RF power coupling to the load. Preferably, the turns of the coil comprise sheets of metal and the coil turns are substantially parallel to each other. Another aspect of the present invention is an apparatus for carrying out processes that use RF power.

### CROSS-REFERENCES

The present application claims benefit of U.S. Provisional Patent Application No. 60/282,081, filed Apr. 7, 2001. The present application is related to U.S. Pat. No. 6,326,584 and U.S. Provisional Patent Application No. 60/282,081, filed Apr. 7, 2001. U.S. Pat. No. 6,326,584 and U.S. Provisional Patent Application No. 60/282,081 are incorporated herein by this reference, in their entirety.

### BACKGROUND

This invention relates to improved methods and apparatus for delivering radio frequency (RF) power for process operations such as plasma processing and RF induction heating.

RF power is extensively used in a wide variety of applications for carrying out process operations. Exemplary of such process operations is RF induction heating. RF induction heating involves coupling RF power to a material that absorbs the RF power and converts the RF power into heat.

In other applications, RF power is used to produce non-thermal plasmas, also referred to as non-equilibrium plasmas. The manufacture of semiconductor devices is one area in which non-thermal plasmas are extensively used. The non-thermal plasmas are used for etch processes wherein the non-thermal plasmas are used to generate reactive species in a gas to accelerate reactions between the species and a solid surface. The etch process can be a general removal of components on the surface as in a cleaning process or the selective removal of material from certain areas on the surface through use of a masking material that has been previously patterned. Non-thermal plasmas are used to promote deposition reactions wherein gas phase species are caused to react to form a solid product that deposits on surfaces.

During the manufacture of semiconductor devices, etch processes involving RF plasmas and deposition processes involving RF plasmas are used repeatedly during the fabrication process. One of the main benefits of using the non-thermal plasma is the ability of the non-thermal plasma to stimulate chemical reactions that would otherwise require temperatures that are too high for use in the fabrication of semiconductor devices.

There are numerous publications and patents describing standard RF power technology. Descriptions of some of the standard technology can be found in United States patents U.S. Pat. No. 4,948,458, U.S. Pat. No. 5,261,962, U.S. Pat. No. 5,436,528, U.S. Pat. No. 5,650,032, and U.S. Pat. No. 5,942,855.

Based on the variety of possible applications for RF power delivery as described above, there are numerous situations in which it would be advantageous to have improved methods and apparatus for processes involving inductively coupled RF power. There is a need for RF power systems that have higher efficiencies for coupling RF power to the load. There is a need for RF power systems capable of providing the desired RF power delivery and where the apparatus has a relatively compact and low-profile configuration. Furthermore, there is a need for improved systems for RF power processing that can couple RF power to large area loads.

### SUMMARY

This invention is related to methods and apparatus that can overcome one or more deficiencies of known RF power delivery systems. Practicing this invention makes it possible to achieve RF power delivery to a load using a system that includes an RF induction coil for which the RF induction coil achieves high RF power coupling efficiency, is capable of high current capacity, and can be fabricated to be compact and have a low-profile.

One aspect of the present invention is a method of coupling RF power to a load such as a load that includes an RF powered plasma and for coupling RF power to a load such as a susceptor that is part of an RF power induction heating system. In one embodiment, the method includes the step of flowing RF current through an RF induction coil having a sufficiently large surface area and a low profile that results in more efficient RF power coupling to the load. Preferably, the turns of the coil comprise sheets of metal and the coil turns are substantially parallel to each other.

Another aspect of the present invention is an apparatus for carrying out processes that use RF power. The apparatus includes a coil for inductively coupling RF power to a load. The coil includes one or more coil turns wherein the coil turn is fabricated from a sheet of metal so that each coil turn has a large surface area in comparison to the standard technology RF power induction coils.

Another aspect of the present invention is an apparatus for carrying out processes that use RF power wherein RF power is coupled to a load using a coil having one or more coil turns. The coil turns are sheets of electrical conductors; the coil turns are supported by a substrate such as a substrate used for fabricating printed circuit boards; the sheets of electrical conductors may be, as an option, interspersed with an electrically insulating material.

Still, another aspect of the present invention is a method of fabricating RF induction coils wherein apparatus according to embodiments of the present invention are fabricated using standard printed circuit board manufacturing techniques to fabricate the coil turns and insulating layers on the substrate.

It is to be understood that the invention is not limited in its application to the details of construction and to the arrangements of the components set forth in the following description or illustrated in the drawings. The invention is capable of other embodiments and of being practiced and carried out in various ways. In addition, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out aspects of the present invention. It is important, therefore, that the claims be regarded as including such equivalent constructions insofar as they do not depart from the spirit and scope of the present invention.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is not intended to define the invention of the application, which is measured by the claims, nor is the abstract intended to be limiting as to the scope of the invention in any way.

The above and still further features and advantages of the present invention will become apparent upon consideration of the following detailed descriptions of specific embodiments thereof, especially when taken in conjunction with the accompanying drawings.

### DESCRIPTION OF THE DRAWINGS

FIG. 1 is a diagram of an embodiment of the present invention.

FIG. 2 is a diagram of an embodiment of the present invention.

FIG. 3 is a diagram of an embodiment of the present invention.

FIG. 4 is a diagram of an embodiment of the present invention.

FIG. 5 is a diagram of an embodiment of the present invention.

FIG. 6 is a diagram of an embodiment of the present invention.

FIG. 7 is a diagram of an embodiment of the present invention.

FIG. 8 is a diagram of an embodiment of the present invention.

FIG. 9 is a diagram of an embodiment of the present invention.

FIG. 10 is a diagram of an embodiment of the present invention.

FIG. 11 is a diagram of an embodiment of the present invention.

### DESCRIPTION

The operation of embodiments of the present invention will be discussed below, primarily, in the context of coupling RF power to gas for generating a plasma such as that used for fabrication of electronic devices. However, it is to be understood that embodiments in accordance with the present invention may be used for applications such as for promoting chemical reactions for applications other than processing semiconductors, and such as for coupling RF power to a load for RF power induction heating, and for transmitting RF power for other applications that use RF power.

In the following description of the figures, identical reference numerals have been used when designating substantially identical elements or steps that are common to the figures.

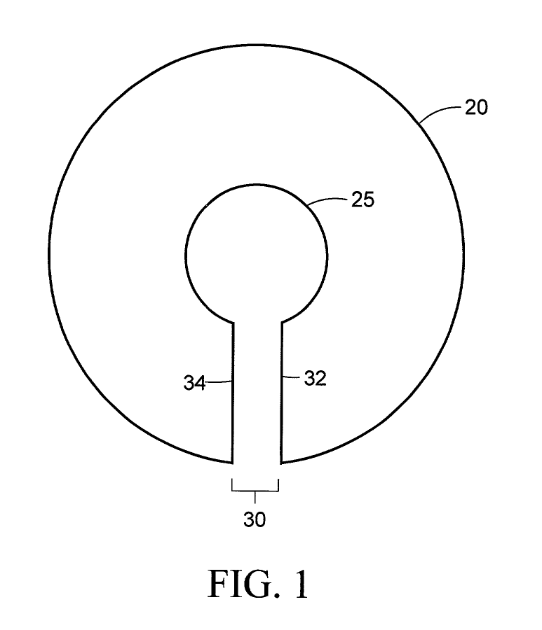

Reference is now made to FIG. 1 wherein there is illustrated a top view of a single coil turn 20 according to one embodiment of the present invention. Coil turn 20, according to one embodiment, comprises an electrical conductor such as a sheet of metal or metal alloys such as those made of metals such as copper, silver, gold, and aluminum. Coil turn 20 has a hole 25. Coil turn 20 has a first edge 32 and a second edge 34 opposite first edge 32. Edge 32 and edge 34 define a slot 30 in coil turn 20 shown in FIG. 1. Slot 30 extends from the periphery of coil turn 20 to hole 25 so as to form a keyway. In one embodiment, coil turn 20 has an outer diameter of about 6 inches (152.4 mm) and an inner diameter of about 2 inches (50.8 mm). In other words, hole 25 has a diameter of about 2 inches (50.8 mm). Of course, in other embodiments the outer diameter for coil 20 may be appropriately sized for the particular application. Similarly, the diameter of the hole can be appropriately selected for the particular application. In some embodiments, the ratio of the diameter of the hole to the diameter of the coil turn is about 1:3.

The thickness of coil turn 20 will depend on the particular application. Specifically, the thickness of coil turn 20 will depend on the electrical conductivity of the conductive material comprising coil turn 20 and upon the desired current flow for the RF power induction. For high currents, the thickness will be larger, whereas for lower currents, the thickness may be smaller. In one embodiment, coil turn 20 has a thickness of about 0.04 inches (about 1 mm).

In some preferred embodiments, coil turn 20 comprises a section of sheet metal. The dimensions of the sheet metal are selected so that coil turn 20 has a large surface and a corresponding large surface area. Specifically, the thickness of coil turn 20 is small in comparison to the length and width dimensions of the coil turn. In one embodiment, coil turn 20 has a thickness of about 0.04 inches (about 1 mm), an outer diameter of about 6 inches (about 150 mm), and an inner diameter of about 2 inches (about 50 mm). For some embodiments of the present invention, large diameters are used for the coil turns so as to produce a large area plasma. Similarly, large diameters may be used for the coil turns used for large are RF induction heating.

A coil having multiple coil turns may include multiple coil turns like coil turn 20. The multiple coils are electrically connected so that the direction of current flow through the coils does not change substantially as a function of position in the coil.

It is to be understood that the shape of coil turn 20 shown in FIG. 1 is only illustrative. Specifically, shapes other than the substantially circular shape shown for coil turn 20 in FIG. 1 can be used in practicing the present invention. Coil turns according to aspects of the present invention may have shapes such as square, rectangular, triangular, or substantially any other geometric shape. For some applications, there may be preferred shapes for the coil turns. For instance, when processing substantially circular workpieces then it may be desirable to have circular coil turns. However, when processing substantially rectangular workpieces it may be desirable to have rectangular coil turns.

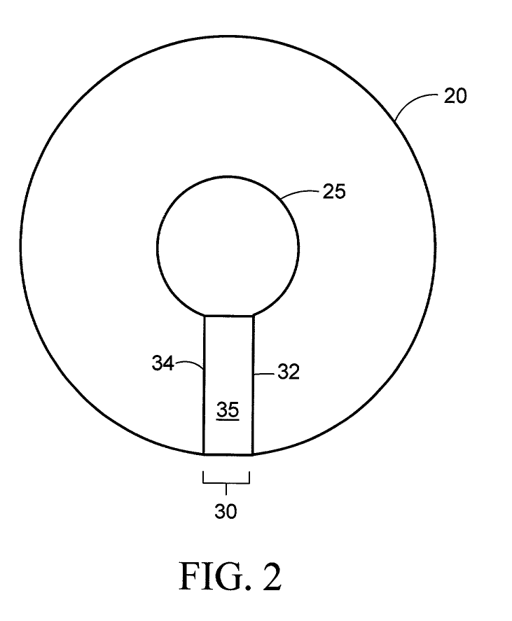

Reference is now made to FIG. 2 wherein there is shown a top view of a multiple turn coil according to an embodiment of the present invention. The top view shows a coil turn 20 that is substantially the same as that described for FIG. 1. Coil turn 20 has a hole 25, a first edge 32, a second edge 34, and a slot 30 defined by edge 32 and edge 34. FIG. 2 further shows inter-coil electrical connection 35. Electrical connection 35 extends from second edge 34 down to first edge 32 of the next coil turn (the next coil turn is not shown in FIG. 2). Electrical connection 35 allows current to flow between adjacent coil turns.

An embodiment of the present invention includes a coil for inductively coupling RF power to a load. The coil includes one or more coil turns wherein the coil turn is fabricated from a sheet of metal or a metal layer so that each coil turn has a large surface area in comparison to the standard technology RF induction coils.

In a preferred embodiment, the coil includes a plurality of substantially non-coplanar coil turns in which the coil turns are made from an electrically conductive sheet. In this embodiment, the coil is substantially helical, and the surface of the sheet is substantially perpendicular to the axis of the coil.

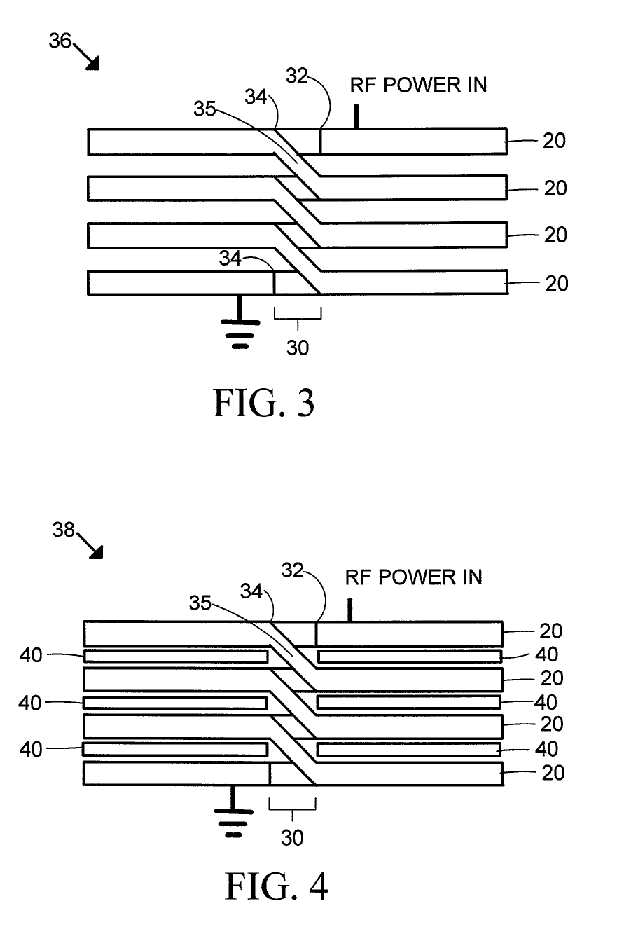

Reference is now made to FIG. 3 wherein there is shown a side view of a multiple turn coil 36 according to an embodiment of the present invention. FIG. 3 shows a 4-turn coil wherein each turn comprises a coil turn 20. Coil turn 20 is essentially the same as that described in FIG. 1 and in FIG. 2. Coil turn 20 comprises a sheet of metal having a hole 25 (not shown in FIG. 3), a first edge 32, and a second edge 34. Edge 32 and edge 34 define a slot 30. FIG. 3 also shows inter-coil electrical connection 35 extending from the second edge 34 of each coil turn 20 to the first edge 32 of each adjacent coil 20 so that current can flow through each coil turn 20. FIG. 3 also shows how an input of RF power can be applied to a location near first edge 32 of the top coil turn 20. In addition, FIG. 3 shows how a ground connection can be made near second edge 34 of the bottom coil turn 20.

Application of RF power as shown in FIG. 3 and grounding as shown in FIG. 3 can allow current to flow through each coil turn 20 and inductively couple RF power into a load suitably disposed for receiving RF power (load not shown in FIG. 3). The arrangement of coil 36 and the load will depend upon the particular application. For instance, if the application involves plasma processing in a plasma chamber then the preferred arrangement would be to position coil 36 proximate to the plasma chamber to more easily couple RF power to the plasma. For RF power induction heating, then the preferred arrangement would be to position coil 36 proximate to the susceptor for absorbing the inductively coupled RF power.

Various methods can be used to provide the inter-coil connection 35. In one embodiment, each coil turn 20 may be a single unit and each unit is electrically connected with an electrical conductor to produce the electric connection to the adjacent coil turn 20. However, in an alternative embodiment, all of the coil turns and inter-coil connections may be formed as a single unit from a single piece of metal. Specifically, the coil turns and inter-coil connections can be fabricated from a single piece of sheet metal. In another embodiment, the coil turns and inter-coil connections can be all machined from a single piece of metal.

Embodiments of present invention can be made so that they have a low profile. In this description, profile refers to the thickness of the multiturn coil. Of course, the thickness of the multiturn coil will depend upon the number of coil turns, the thickness of each individual coil turn, and the distance between adjacent coil turns. Consequently, a low profile can be obtained by using coil turns that are thin metal sheets or metal films and having the coil turns closely spaced to the adjacent coil turns.

Further, it is to be understood that embodiments of the present invention may have, as an option, multiple coil turns for which one or more of the coil turns have diameters that are not equal to those of the other coil turns.

Reference is now made to FIG. 4 wherein there is shown a side view of a multiple turn coil 38. Coil 38 is substantially the same as coil 36 shown in FIG. 3 with the exception that coil 38 further comprises an insulator 40 positioned between the coil turns 20.

Insulator 40 serves to substantially prevent discharge between the coil turns 20. An advantage of having insulator 40 is that insulator 40 allows the coil turns to be more closely spaced and can permit coil 38 to have a more compact overall structure that is thin and presents a low profile. Specifically, the total thickness for coil 38 can be reduced for some embodiments of the present invention as a result of having insulator 40. In other words, by selecting insulator 40 so that it has superior dielectric properties with respect to, for example, air, the spacing between the coil turns can be made smaller than is possible when there is only air between the coil turns.

Another advantage of using the insulators is that a large inductance coil can be formed within a very small profile. The coupling of the magnetic field is a function of each coil turn's distance from the load. As a result of reducing the distance, by using the insulators, the coupling of power to the load can be improved.

A variety of materials can be used for insulator 40 provided that the material has sufficient electrical resistance. Examples of some materials that can be used for insulator 40 include sheets of Teflon, sheets of paper, deposited layers of insulators, glass, quartz, polymers, and other insulating materials. The thickness of insulator 40 is unimportant so long as insulator 40 is capable of providing sufficient electrical isolation.

In yet another embodiment of the present invention, coil 38 can be cooled by methods such as attaching cooling elements such as cooling coils to one or more of the coil turns. The large area of the coil turns is particularly advantageous with respect to achieving efficient heat removal from the coil during operation. Note, cooling coils are not shown in the figures.

Embodiments of the present invention are particularly suited for plasma processing wherein the RF power is coupled to an ionizable gas to produce a plasma for stimulating chemical reactions. Exemplary reactions include reactions for synthesizing chemical products, reactions for decomposing chemical compounds, and reactions for surface treatment such as ashing.

Embodiments of the present invention can be used to carry out plasma processing for which the plasma processing includes plasma treatment of a workpiece. Example workpieces include workpieces such as semiconductor wafers that are subjected to plasma processes used in the fabrication of electronic devices and workpieces subjected to plasma processes for fabrication of optical elements, thin-film transistors, flatpanel displays, and other electronic devices.

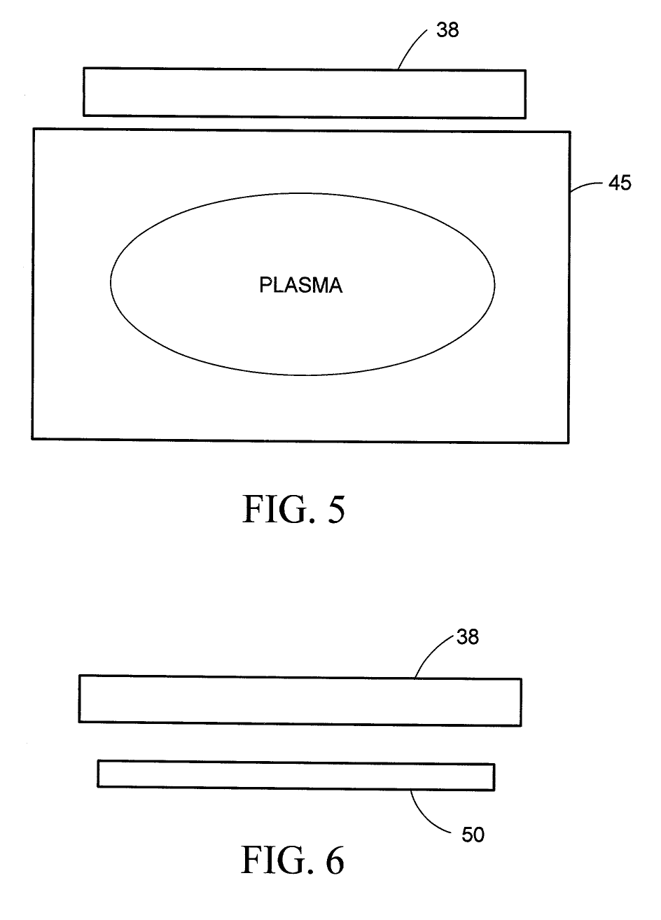

Reference is now made to FIG. 5 wherein there is shown an exemplary arrangement for coil 38 and a plasma chamber 45 according to one embodiment of the present invention. In this embodiment, coil 38 is located near the plasma chamber and is outside of plasma chamber 45. In this configuration, plasma chamber 45 should be capable of allowing RF power to enter the chamber. In a preferred configuration, plasma chamber 45 includes a material that is substantially transparent to RF power so that the RF can be provided to the interior of plasma chamber 45.

Those skilled in the art will understand that coil 38 can be placed inside plasma chamber 45 and that such a location may be advantageous for some applications. For purposes of illustration, a plasma is shown in plasma chamber 45.

In a preferred embodiment, plasma chamber 45 is capable of containing a gas at suitable pressure for generating the plasma. Plasma chambers of this type are well known in the art. Low-pressure plasma processing chambers, such as vacuum plasma processing chambers, are extensively used in applications such as plasma processes for electronic device fabrication and optical device fabrication.

Embodiments of the present invention are particularly suited for plasma processing wherein the RF power is coupled to an ionizable gas to produce a plasma for stimulating chemical reactions. Exemplary reactions include reactions for synthesizing chemical products, reactions for decomposing chemical compounds, and reactions for surface treatment.

Embodiments of the present invention can be used to carry out plasma processing for which the plasma processing includes plasma treatment of a workpiece. Example workpieces include workpieces such as semiconductor wafers that are subjected to plasma processes used in the fabrication of electronic devices, workpieces subjected to plasma processes for fabrication of optical elements and devices, and workpieces such as those used for fabricating flat panel display devices.

Embodiments of the present invention include plasmas processes such as those used for semiconductor device fabrication. Example processes include etching, deposition, surface cleaning, doping, oxidation, drying, photoresist stripping, parts cleaning, reaction chamber cleaning, and annealing.

Reference is now made to FIG. 6 wherein there is shown an exemplary arrangement for coil 38 and a susceptor 50 for RF induction heating. RF induction heating involves coupling RF power to a material, such as susceptor 50 or other workpiece that absorbs the RF power and converts the RF power into heat. In other words, the currents induced in material by the RF power are converted into heat because of the electrical resistance of the material that absorbs the RF power. In this manner, the RF power can be used to heat susceptor 50 without having physical contact between the power source and the object because the RF power is coupled to susceptor 50 from coil 38. Coil 38 should be positioned so as to be able to couple RF power to susceptor 50.

Alternatively, the workpiece may be in contact with or near susceptor 50 so as to receive heat. Specifically, susceptor 50 absorbs the RF power and creates heat. The heat is then transferred to the workpiece by conduction, convection, or radiation.

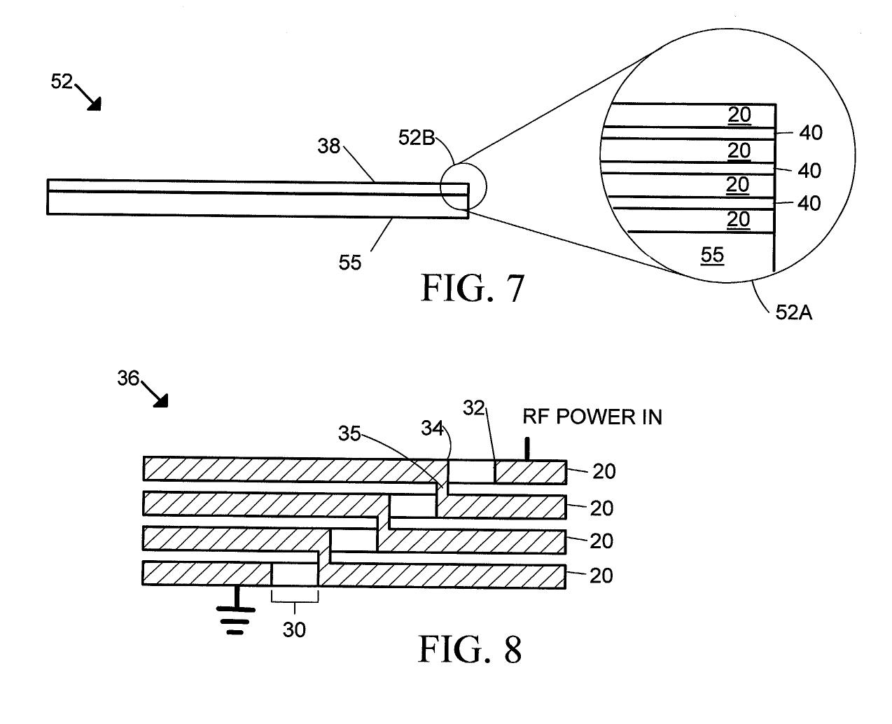

As indicated earlier, embodiments of the present invention may include thin sheets of electrical conductors for coil turns suitable for RF power induction to a load. In some embodiments, the thin sheets of conductors may be used after forming the coil turns on a substrate. One example of a suitable substrate is a substrate such as that typically used in the fabrication of printed circuit boards. For further description of this type of embodiment of the present invention, reference is now made to FIG. 7.

FIG. 7 shows an apparatus 38 for RF power induction. Apparatus 38 includes an RF power induction coil 38 according to an embodiment of the present invention. Coil 38 is substantially the same as that presented in FIG. 4. Also shown in FIG. 7 is a substrate such as a printed circuit board substrate 55. Coil 38 is supported by substrate 55. FIG. 7 also shows a magnified view 52A of a section 52B of apparatus 52. The magnified view 52A shows coil turns 20, insulators 40, and substrate 55.

In some embodiments of the present invention, coil turns 20 may have individual thicknesses down to about one millimeter or less, such as in the sub-micrometer thickness range. It is to be understood that the individual thickness of the coil turns will be at least partially determined by the magnitude of the RF power and the magnitude of the resistance of the coil. Specifically, any thickness can be used for the individual coil turns provided the resistance of the coil is not too high.

Coil turns having a thickness in the sub-micrometer range can be made using fabrication techniques such as those used for manufacturing printed circuit boards and integrated circuits. The techniques used for fabricating printed circuit boards and integrated circuits are well known.

The thickness of the insulator will depend upon the electrical characteristics of the insulating material. However, with commonly available insulators the thickness may be in the sub-micrometer range. Some embodiments of the present invention include insulators having thicknesses like those of insulators used in printed circuit boards and integrated circuits. Insulators for some embodiments of the present invention having a thickness in the sub-micrometer range can be made using fabrication techniques such as those used for manufacturing printed circuit boards and integrated circuits.

Optionally, substrate 55 may be selected to have properties that provide strength and durability for the coil turns. In some embodiments, substrate 55 may be substantially rigid. Alternatively, in other embodiments it may be preferable to have a substrate that is substantially flexible.

Use of a substrate allows the coil turns to be more easily deposited as layers or films of material using standard metal deposition processes such as electroplating, evaporative deposition, sputter deposition, and chemical vapor deposition. The coil turns can be patterned using standard lithography and etching techniques. Advantageously, standard printed circuit board fabrication technology allows production of multiple layer conductors interspersed with electrically insulating layers that are suitable for producing embodiments of the present invention. Use of printed circuit board fabrication technology allows embodiments of present invention to be manufactured economically and easily.

An embodiment of a method according to the present invention of fabricating RF induction coils on a substrate may include the steps of: providing a suitable substrate; depositing an electrically conductive layer on the substrate; defining a pattern in the conductive layer to form a coil turn; depositing an electrically insulating layer over the conductive layer; depositing a subsequent electrically conductive layer on the insulating layer; defining a pattern in the subsequent conductive layer to form a coil turn; and electrically connecting the coil turns. As an option, steps in the process can be repeated until a desired number of coil turns are formed.

Reference is now made to FIG. 8 wherein there is shown a side view of a multiturn coil 36 according to one embodiment of the present invention. The embodiment shown in FIG. 8 is substantially the same as that shown in FIG. 3 with the exception that the arrangement of slots 30 are modified. Specifically, FIG. 8 shows an embodiment where slots 30 are not aligned, whereas the embodiment presented in FIG. 3 shows slots 30 as being substantially aligned.

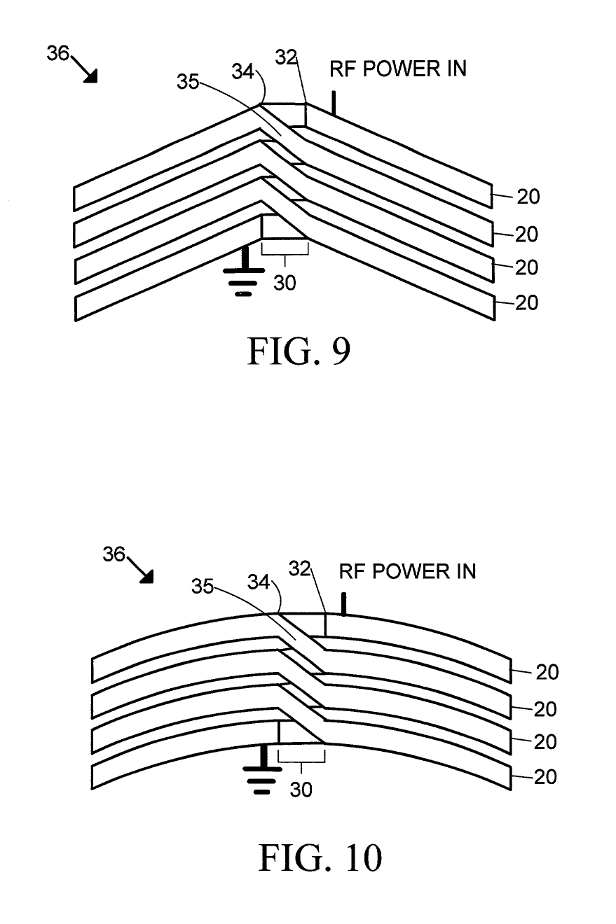

Embodiments of the present invention may be configured so that the coils are substantially flat. However, other embodiments of the present invention may include multiturn coils that are substantially not flat. For instance, embodiments of the present invention may have coil turns that are conical in shape. Alternatively, embodiments of the present invention may have coil turns that are curved in shape such as having curves defined by sections of a sphere or other curves such as those defined by sections of an ellipse and other geometric curves. FIG. 9 shows a side view of an embodiment of the present invention that has coil turns having a conical shape. FIG. 10 shows a side view of an embodiment according to the present invention that has coil turns having a curved shape. The embodiment shown in FIG. 9 and FIG. 10 are substantially the same as those shown in FIG. 3.

A preferred embodiment of the present invention includes an RF induction coil for transmitting RF power from an RF power source. The coil includes a plurality of coil turns; the coil turns include a sheet of electrical conductor. The coil turns are substantially non-coplanar. Furthermore, the surface of the sheet is substantially nonparallel to the axis of the coil. In a more preferred embodiment, the surface of the sheet is substantially perpendicular to the axis of the coil.

It is to be understood that that the surface of the sheet of electrical conductor for embodiments of the present invention can be oriented so that the surface of the sheet and the axis of the coil define an angle between 0 degrees and 180 degrees, and subranges subsumed therein.

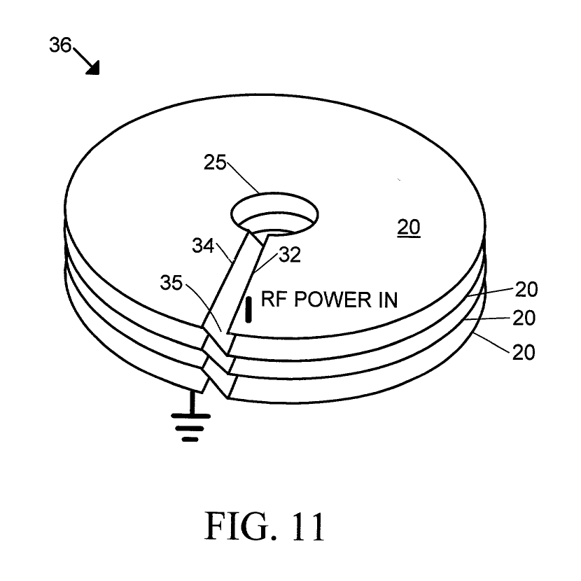

To further illustrate embodiments of the present invention, reference is now made to FIG. 11. A perspective view of a multiturn coil that is essentially the same as that described in FIG. 3 is presented in FIG. 11. FIG. 11 shows multiturn coil 36 having four coil turns 20. Each coil turn has a first edge 32 and a second edge 34. Each coil turn 20 also has a hole 25 located at about the center of the coil turns. Each coil turn 20 is electrically connected with the next coil turn by an inter-coil electrical connection 35.

Multiturn coil 36 is sufficiently electrically conductive so that an RF power source can be connected with multiturn coil 36 so that multiturn coil is capable of inductively coupling RF power to a load (the power source and load are not shown in FIG. 11). Optionally, electrical insulators can be sandwiched between the coil turns so as to substantially prevent arcing between the coil turns (electrical insulators not shown in FIG. 11).

Numerous commercially available RF power sources are suitable for use in embodiments of the present invention. A typical RF power source includes an RF power amplifier and a match network. The RF power source is configured so as to be able to accomplish impedance matched RF power delivery to a load through an RF power coupling element such as an RF induction coil. Some embodiments of the present invention include an RF power source and RF induction coils as described herein and their equivalents.

It is to be understood that the figures presented in this application are not to be interpreted as scaled drawings: these figures are intended only to illustrate aspects of the present invention. Those skilled in the art will recognize that embodiments of the present invention may include multiturn coils where the total thickness of the multiturn coil from the beginning of the first coil turn to the end of the last coil turn may be less than about 1 inch (about 25 mm). Preferably, the thickness is less than about 0.5 inch (about 12.7 mm), and more preferably less than about 0.25 inch (about 6.3 mm).

Embodiments of the present invention fabricated using methods such as printed circuit board manufacturing methods and integrated circuit manufacturing methods may include multiturn coils with a total thickness less than about 0.04 inch (about 1 mm).

While there have been described and illustrated specific embodiments of the invention, it will be clear that variations in the details of the embodiments specifically illustrated and described may be made without departing from the true spirit and scope of the invention as defined in the appended claims and their legal equivalents.

What is claimed is:

1. An apparatus for inductively coupled RF power process operations, the apparatus comprising:
a process chamber;
an RF power source; and
an RF power induction coil, the RF power induction coil having substantially non-coplanar coil turns, at least one of the coil turns comprising an electrically conductive sheet having a large surface area, the coil being connected with the RF power source so as to receive RF power, the large surface area being oriented substantially perpendicularly to magnetic field lines caused by RF current flow through the coil, the coil being disposed so as to couple RF power to the chamber for the process operations.

2. An apparatus according to claim 1, wherein the at least one coil turn comprises multiple coil turns.

3. An apparatus according to claim 2, wherein at least a portion of the multiple coil turns are perpendicular to the magnetic field lines.

4. An apparatus according to claim 1, wherein the coil is outside of the process chamber and the process chamber comprises materials that are substantially transparent to RF power.

5. An apparatus according to claim 1, wherein the conductive sheet comprises a deposited layer.

6. An apparatus according to claim 1, further comprising a substrate, the conductive sheet being at least partially supported by the substrate.

7. An apparatus according to claim 1, further comprising an electrical insulator sandwiched between at least two of the coil turns.

8. An apparatus according to claim 7, wherein the coil comprises about four coil turns and the thickness of the coil is less than about 0.5 inch (about 12.7 mm).

9. An apparatus according to claim 7, wherein the coil thickness is less than about 0.25 inch (about 6.3 mm).

10. An apparatus according to claim 1, wherein the inside diameter of the coil and outside diameter of the coil have a ratio of about 1:3.

11. An apparatus according to claim 7, wherein the substrate comprises a printed circuit board and the coil turns comprise deposited layers of an electric conductor.

12. An apparatus according to claim 1, wherein the process chamber comprises a plasma chamber capable of receiving a gas for generating a plasma.

13. An apparatus according to claim 1, wherein the process chamber is capable of receiving a semiconductor wafer for plasma processing.

14. An apparatus according to claim 1, wherein the process chamber includes a vacuum plasma processing chamber capable of sustaining a non-thermal plasma for semiconductor device fabrication processes.

15. An apparatus according to claim 1, wherein the process chamber includes a vacuum plasma processing chamber capable of sustaining a non-thermal plasma for semiconductor device fabrication processes selected from the group consisting of etching, deposition, surface cleaning, doping, oxidation, drying, photoresist stripping, reaction chamber cleaning, and annealing.

16. An apparatus according to claim 1, wherein the process chamber is capable of receiving the RF power to produce heat for an RF power induction heating process.

17. An apparatus for inductively coupling RF power, the apparatus comprising:
an RF power source; and
an RF power induction coil, the RF power induction coil having a plurality of coil turns, the coil turns comprising an electrically conductive sheet, the coil being substantially helical, the surface of the sheet being substantially perpendicular to the axis of the coil, the coil being connected with the RF power source so as to receive RF power.

18. An apparatus for inductively coupling RF power, the apparatus comprising:
an RF power source;
a substantially solid insulator; and
an RF power induction coil, the RF power induction coil having about four coil turns, the coil turns comprising a sheet of electrical conductor so as to have a large surface area such that the ratio of the outer diameter of the coil turn to the thickness of the coil turn is greater than or equal to about 6:0.04, the insulator being sandwiched between the coil turns, the coil having a first end and a second end opposite the first end, the first end of the coil being attached to the RF power source so as to receive RF power, the second end of the coil being capable of connection to electrical ground, and the thickness of the coil being less than about 0.25 inch (about 6.3 mm).

19. An RF induction coil for transmitting RF power from an RF power source, the coil comprising:
a plurality of coil turns, the coil turns comprising a sheet of electrical conductor, the coil turns having an inner diameter and an outer diameter, the coil turns being substantially non-coplanar, the surface of the sheet being substantially nonparallel to the axis of the coil.

20. The RF induction coil of claim 19 wherein the surface of the sheet is substantially perpendicular to the axis of the coil.

21. The RF induction coil of claim 19 wherein the surface of the sheet and the axis of the coil define an angle between 0 degrees and 180 degrees.

22. A method of fabricating RF induction coils, the method comprising the steps of:
1. providing a substrate;
2. depositing an electrically conductive layer on the substrate;
3. defining a pattern in the conductive layer and forming a coil turn;
4. depositing an electrically insulating layer over the conductive layer;
5. depositing a subsequent electrically conductive layer on the insulating layer;
6. defining a pattern in the subsequent conductive layer and forming a subsequent coil turn substantially concentric with the previous coil turn; and
7. electrically connecting the coil turns.

23. A method of inductively coupling RF power, the method comprising the steps of:
providing an RF power source; and
applying RF power from the source to an RF power induction coil, the RF power induction coil having a plurality of coil turns, the coil turns comprising an electrically conductive sheet, the coil being substantially helical, and the surface of the sheet being substantially perpendicular to the axis of the coil.
